(19) United States
(12) Patent Application Publication
(10) Pub. No.: US 2019/0304938 A1
(43) Pub. Date: Oct. 3, 2019

(54) SYSTEMS AND METHODS FOR WAFER-LEVEL MANUFACTURING OF DEVICES HAVING LAND GRID ARRAY INTERFACES

(71) Applicant: wiSpry, Inc., Irvine, CA (US)

(72) Inventor: Rameen Hadizadeh, Tustin, CA (US)

(21) Appl. No.: 16/369,967

(22) Filed: Mar. 29, 2019

Related U.S. Application Data
(60) Provisional application No. 62/649,807, filed on Mar. 29, 2018.

(51) Int. Cl. H01L 23/00; H01L 21/56

(52) U.S. Cl. CPC H01L 24/03; H01L 2224/24137; H01L 21/568; H01L 24/05; H01L 24/24; H01L 24/82; H01L 2224/05024; H01L 2224/03462; H01L 2224/03914; H01L 2224/82106; H01L 2224/05562; H01L 2224/05647; H01L 2224/05147; H01L 2224/24101; H01L 21/561

(57) ABSTRACT

The present subject matter relates to systems and methods for wafer-level manufacturing of devices having land grid array interfaces. Such devices can include a semiconductor die comprises an active surface including one or more electrical contacts, conductive studs in a directly metallized connection with the electrical contacts, an over-mold structure substantially surrounding the active surface of the semiconductor die and the conductive studs, and conductive contacts formed in an outer surface of the over-mold structure. In this configuration, each of the conductive contacts is connected to one of the conductive studs, and the conductive contacts define a land grid array interface on the outer surface of the over-mold structure.

### CROSS-REFERENCE TO RELATED APPLICATION

The present application claims priority to U.S. Provisional Patent Application Ser. No. 62/649,807, filed Mar. 29, 2018, the entire disclosure of which is incorporated by reference herein.

### TECHNICAL FIELD

The subject matter disclosed herein relates generally to packaging of integrated circuits. More particularly, the subject matter disclosed herein relates to systems and methods for wafer-level manufacturing of devices having land grid array interfaces.

### BACKGROUND

Wafer-level chip-scale packaging allows for integration of wafer fabrication, packaging, test, and burn-in at wafer level in order to streamline the manufacturing process undergone by an integrated circuit device from silicon start to customer shipment. Such processes have shown to be particularly useful in small electronic devices, such as smartphones and other hand-held devices, due to size constraints.

Conventional chip-scale devices are still practically limited, however, in how small the final package can be. In particular, for example, when used in surface mount technology processes, such packages commonly use soldered connections (e.g., solder balls) to connect the device circuitry to an attached system (e.g., PCB). Such solder connections generally add electrical resistance and height (e.g., adding about 200 μm) to the device connection, which increase both the package size and the electrical path length from the integrated circuit device to the PCB.

As a result, it would be desirable for systems and methods for wafer-level manufacturing of devices to provide improved connections between the integrated circuits and the devices to which they are connected.

### SUMMARY

In accordance with this disclosure, systems and methods for wafer-level manufacturing of devices having land grid array interfaces are provided. In one aspect, a method of manufacturing an integrated circuit device is provided. The method includes, for each of a plurality of semiconductor dies, depositing one or more conductive studs in a directly metallized connection with a respective one of the plurality of semiconductor dies. A first over-mold material layer is deposited over the one or more conductive studs and the plurality of semiconductor dies, and one or more conductive contacts are deposited in communication with the one or more conductive studs to define a land grid array interface. In some embodiments, a second over-mold material layer is deposited about the one or more conductive contacts such that the one or more conductive contacts define a land grid array interface on a surface of the second over-mold material layer.

In another aspect, an integrated circuit device is provided in which a semiconductor die comprises an active surface including one or more electrical contacts. One or more conductive studs are in a directly metallized connection with the one or more electrical contacts. An over-mold structure substantially surrounds the active surface of the semiconductor die and the one or more conductive studs, the over-mold structure defining an outer surface. One or more conductive contacts are formed in the outer surface of the over-mold structure, wherein each of the one or more conductive contacts is connected to one of the one or more conductive studs, and wherein the one or more conductive contacts define a land grid array interface on the outer surface of the over-mold structure.

Although some of the aspects of the subject matter disclosed herein have been stated hereinabove, and which are achieved in whole or in part by the presently disclosed subject matter, other aspects will become evident as the description proceeds when taken in connection with the accompanying drawings as best described hereinbelow.

### BRIEF DESCRIPTION OF THE DRAWINGS

The features and advantages of the present subject matter will be more readily understood from the following detailed description which should be read in conjunction with the accompanying drawings that are given merely by way of explanatory and non-limiting example, and in which:

FIG. 1 is a side view of an integrated circuit device according to an embodiment of the presently disclosed subject matter;

FIGS. 2A through 2C are plan views of arrangements of semiconductor dies in a reconstituted wafer or panel form according to embodiments of the presently disclosed subject matter;

FIGS. 3A through 14 are side views of steps in a method for manufacturing an integrated circuit device according to an embodiment of the presently disclosed subject matter; and

FIG. 15 is a plan view of an arrangement of semiconductor dies in a reconstituted wafer or panel form according to an embodiment of the presently disclosed subject matter.

### DETAILED DESCRIPTION

The present subject matter provides systems and methods for wafer-level manufacturing of devices having land grid array interfaces. In one aspect, the present subject matter provides an integrated circuit device. Referring to FIG. 1, in some embodiments, the integrated circuit device, generally designated 100, includes a semiconductor die 110 (e.g., a CMOS or MEMS integrated circuit) having an active surface 112 (including one or more electrical contacts). One or more conductive studs 130 are in direct communication with die 110 (e.g., in communication with the electrical contacts). An over-mold structure 120 substantially surrounds active surface 112 of die 110 and conductive studs 130, with over-mold structure 120 defining an outer surface 125. In some embodiments, over-mold structure 120 serves as a passivation layer for conductive studs 130 and/or for sides of die 110. One or more conductive contacts 135 are formed in outer surface 125 of over-mold structure 120. In this configuration, each of conductive contacts 135 is connected to one of the conductive studs 130, and the conductive contacts 135 define a land grid array interface on outer surface 125 of over-mold structure 120. Such a configuration provides that an electrical interconnect from die to die and to pad is directly metallized without solder and without the use of a pre-fabricated interposer. In some embodiments, for example, the connection between die 110 and conductive contacts 135 does not require the use of solder and is sufficiently complete with no redistribution layer.

Such a configuration allows integrated circuit device 100 to be integrated with a PCB via direct surface-mount technology (SMT) processes, such as a flip-chip arrangement. Although solder is still required to connect or surface mount the final device to the PCB, in some embodiments, a reduced volume of solder can be used as compared with a traditional solder ball connection. In this way, whereas conventional LGA systems require that the integrated circuit device itself be flip-chip bonded to an intermediate routing level (e.g., often referred to as a “substrate” in the case of traditional LGA packaging), the present wafer-level LGA approach eliminates the solder connection to such a flip-chip solder interconnect. Thus, compared to many conventional SMT implementations that use such an intermediate routing level, the direct connection to the circuits of die 110 by way of the land grid array (LGA) finish can provide significant advantages, such as a reduction in bond-line spacing, a reduction in X/Y/Z package size, and/or a reduced path length from the integrated circuit to the PCB

To achieve a package having these advantages, in another aspect, the present subject matter provides a method of manufacturing an integrated circuit device having a direct connection interface. In some embodiments, the kind of packages described above can be constructed using a wafer reconstitution method and wafer-level processing by which a plurality of semiconductor dies 110 is arranged in a desired arrangement. For example, in some embodiments, dies 110 can be singulated from a wafer and arranged in a reconstituted wafer or panel form, such as in a manner similar to traditional fan-out wafer reconstitution methods in which dies 110 are held on a common carrier. In some embodiments, this arrangement can involve bumping the wafer, then dicing the wafer, and arranging the bumped dies on an adhesive carrier for the rest of the flow. In some other embodiments, the wafer can be diced, the individual dies can be arranged on an adhesive carrier, and then the dies can be molded, planarized, and then bumped. Although a few examples are disclosed here, those having ordinary skill in the art will recognize that any of a variety of other processing methods can be used to arrange dies 110 in a desired configuration.

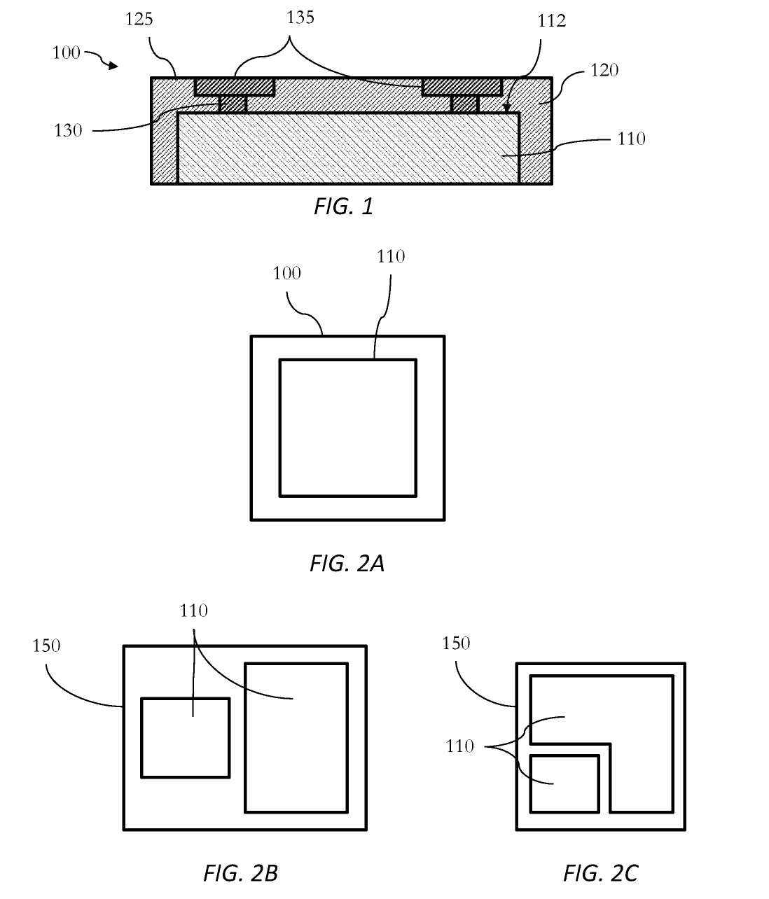

In some embodiments, each die 110 can eventually be singulated into a single-element integrated circuit device 100 as shown in FIG. 2A. Alternatively, in some embodiments, multiple dies 110 can be provided in a multi-die package 150, wherein each of dies 110 can be provided in a conventional shape (e.g., square or rectangular), such as is shown in FIG. 2B, which illustrates two rectangular dies 110 arranged side-by-side in multi-die package 150. Alternatively, each die 110 can be plasma-diced into more complex shapes. As shown in FIG. 2C, for example, dies in multi-die package 150 can be non-rectangular (e.g., L-shape) for the added benefit of consuming the least amount of space within the package and achieving an overall square or low-aspect-ratio rectangular package form factor. In some embodiments, the size of each die 110 can be limited due to differences between the coefficients of thermal expansion of die 110 and later-deposited materials. (e.g., having a die with an X/Y size that is less than about 6 mm×about 6 mm, although those having ordinary skill in the art will recognize that packaging is accommodating larger and larger die as technology and materials advance)

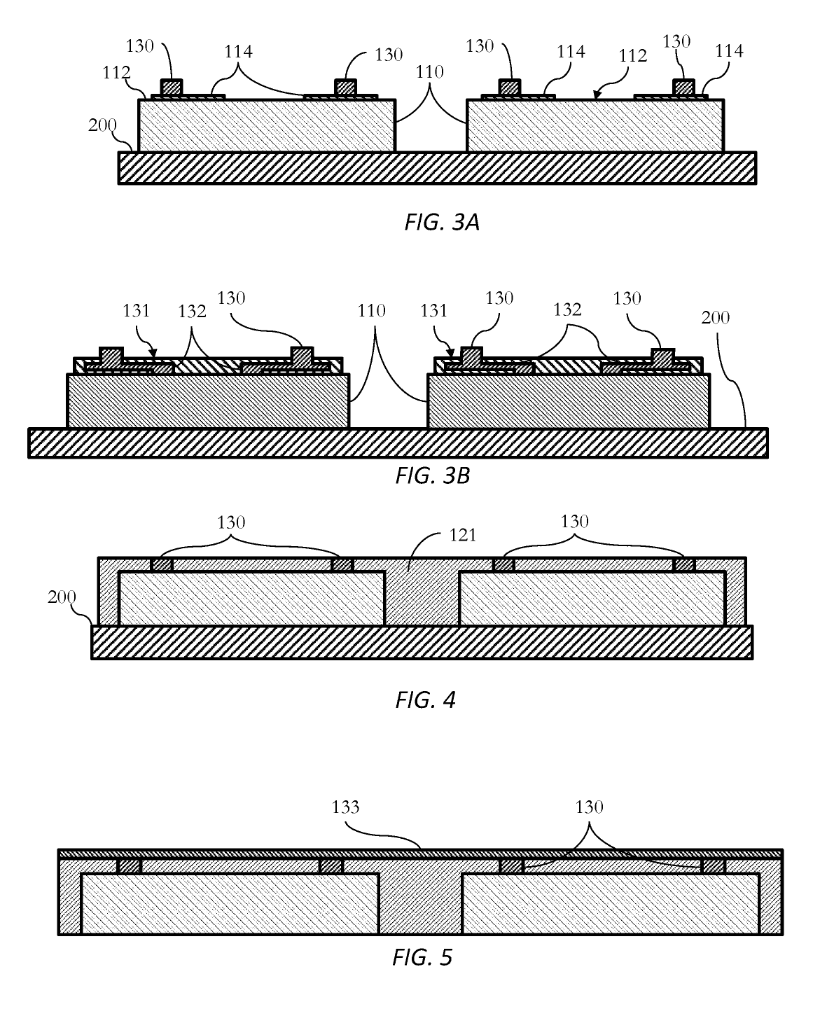

Referring to FIGS. 3A and 3B, dies 110 are arranged in a desired configuration, such as by mounting dies 110 on an adhesive carrier 200 (e.g., with a passive side of each of dies 110 being positioned against carrier 200). With dies 110 arranged in such a configuration, one or more conductive stud 130 is deposited in direct communication with each die 110. Specifically, conductive studs 130 can be provided in a desired pattern to provide communication with one or more electrical contacts 114 on an active surface 112 of each die 110. In some embodiments, conductive studs 130 are provided in registry with electrical contacts 114 on active surface 112 of each die 110, such as is illustrated in FIG. 3A. In some other embodiments, each stud 130 is a terminal of a redistribution layer (RDL) 131 or other arrangement comprising one or more levels of conductors 132 that form a directly metallized connection to active surface 112 of a respective die 110, such as is illustrated in FIG. 3B. In any configuration, studs 130 are each part of a directly metallized connection to a respective die 110. As used herein, the term “directly metallized connection” refers to a structure that forms an electrical connection to a respective die 110 without solder and without the use of a pre-fabricated interposer. In some embodiments, such a directly metallized connection is formed by plating or otherwise depositing studs 130 on the die 110, either directly or in combination with one or more thin film conductor layers, such as conductors 132. In some embodiments, studs 130 and/or conductors 132 are formed from copper or any of a variety of other high-conductivity and/or high-melting-point metals.

Next, as illustrated in FIG. 4, a first over-mold material layer 121 is deposited over studs 130 and dies 110. In some embodiments, first over-mold material layer 121 comprises an epoxy molding compound, although any of a variety of dielectric materials (e.g., polymer, epoxy) or combination of materials can be used as first over-mold material layer 121 in some implementations. As needed, a portion of first over-mold material layer 121 can be removed, such as by grinding, to expose studs 130. In some embodiments, the material is removed in a “panel front grind” process that is like the methods used for fan-out wafer-level packaging processes. In some embodiments, once first over-mold material layer 121 is deposited over dies 110, carrier 200 can be either removed or retained for the remainder of the process.

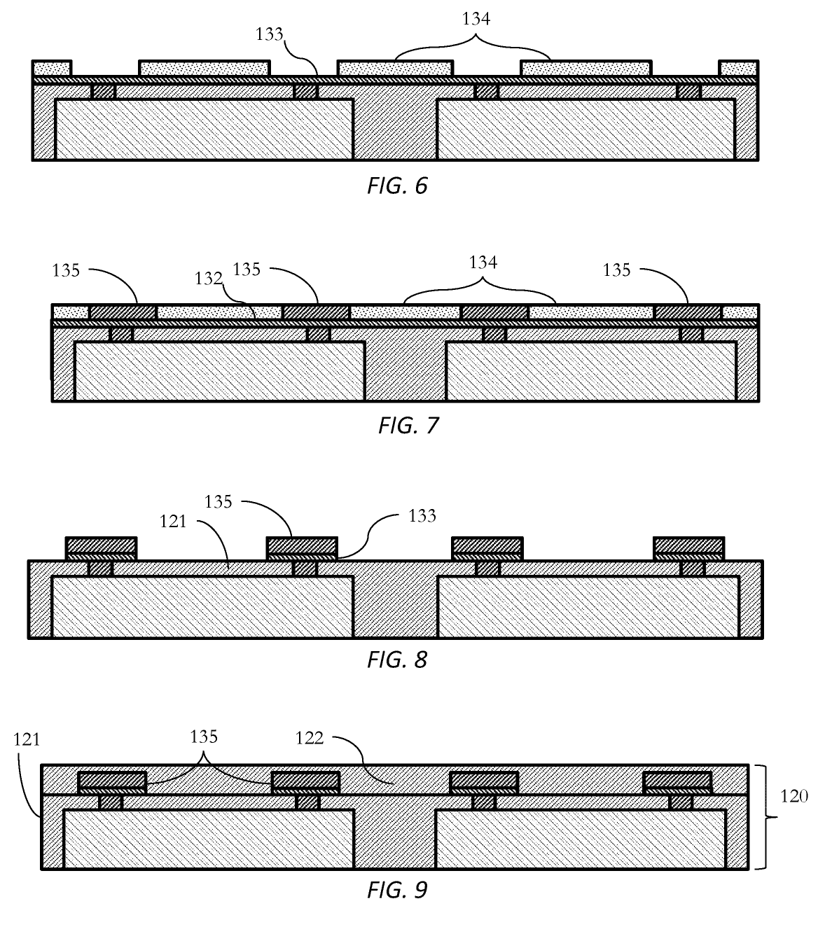

In some embodiments, a seed metal layer 133 can be deposited, such as by sputtering, as shown in FIG. 5 to provide an improved connection for later-deposited materials to studs 130. In some embodiments, seed metal layer 133 can comprise copper, although aluminum, nickel, gold, titanium, vanadium, silver, chromium, or possibly other transition or post-transition metals can be used for seed metal layer 133. Next, a contact resist pattern 134 that defines a desired arrangement of the land grid array interface can be deposited over seed metal layer 133 as shown in FIG. 6, and one or more conductive contacts 135 can be deposited (e.g., by electroplating) in the desired arrangement as shown in FIG. 7. Conductive contacts 135 can be formed in any of a variety of desired shapes, such as to form circular or rectangular pads. Referring next to FIG. 8, resist pattern 134 can be removed (e.g., stripped), and seed metal layer 133 can be etched, such as to remove it from un-plated portions of first over-mold material layer 121. In some embodiments, conductive contacts 135 define the land grid array interface that provides the directly-metallized electrical interconnect from die to die and to pad without solder and without the use of a pre-fabricated interposer as discussed above.

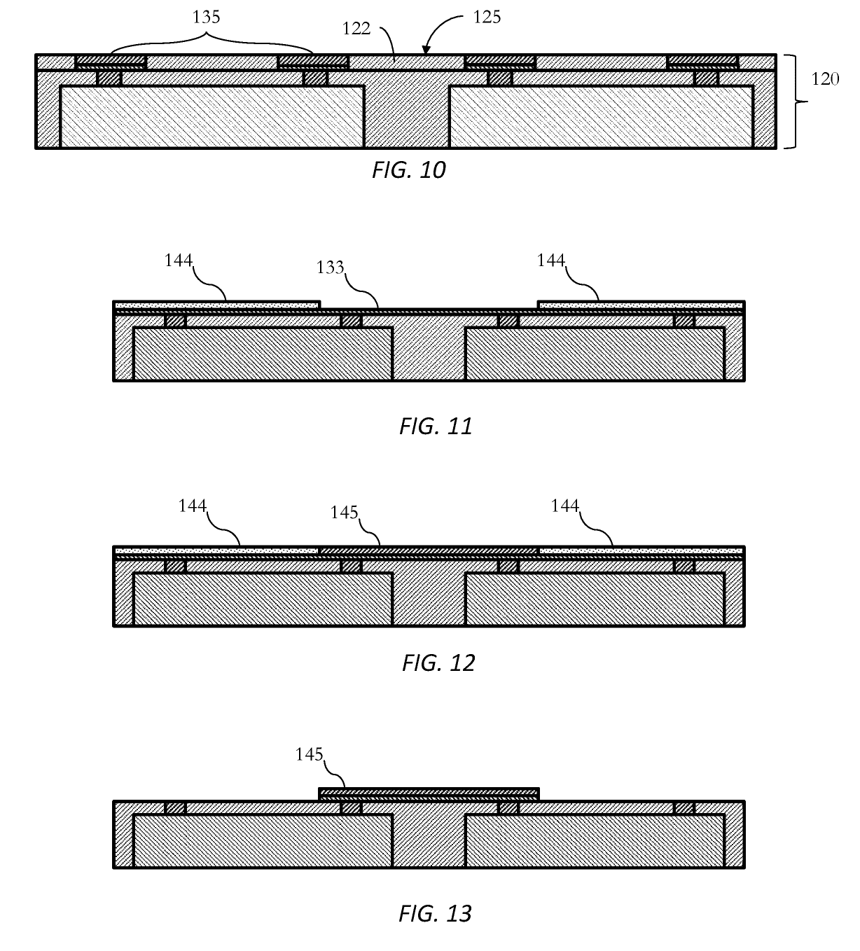

Alternatively, in some embodiments, further processing can refine the surface of the land grid array interface as desired. As illustrated in FIG. 9, for example, a second over-mold material layer 122 can be deposed about conductive contacts 135 over first over-mold material layer 121. In some embodiments, second over-mold material layer 122 is composed of the same material as first over-mold material layer 121 (e.g., an epoxy molding compound), and these material layers can be substantially integrated to together define a substantially unitary over-mold structure 120. Referring next to the step illustrated in FIG. 10, at least a portion of second over-mold material layer 122 can be removed, such as by grinding, to expose conductive contacts 135 such that conductive contacts 135 define a land grid array interface on a surface 125 of second over-mold material layer 122.

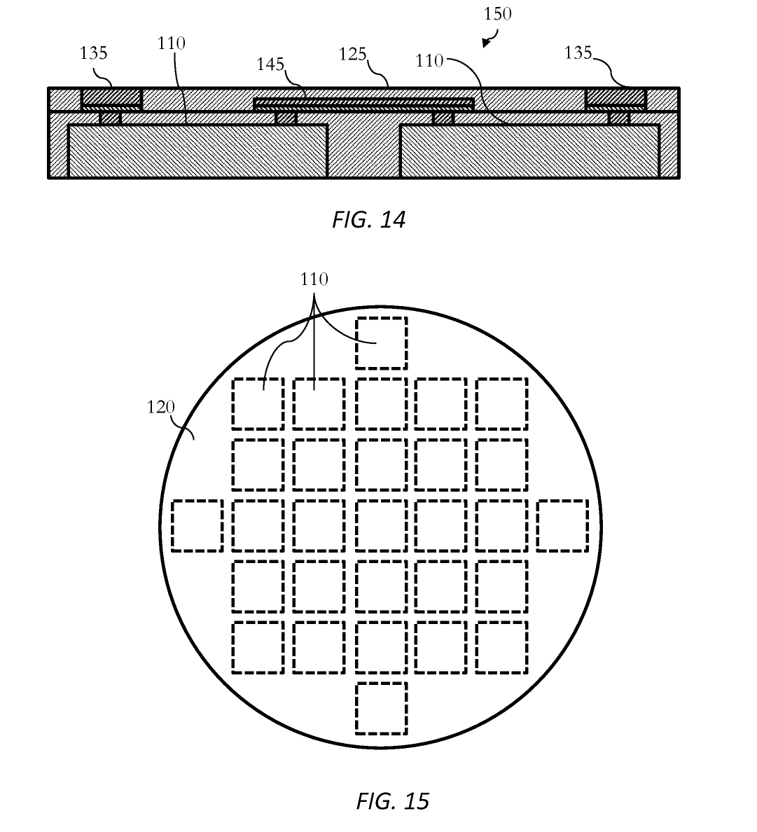

Alternatively or in addition, in some embodiments, the method of manufacturing an integrated circuit device having a direct connection interface can include steps of integrating multiple dies 110 together, such as to provide a multi-die package 150 as discussed above. Such an integration can include connecting studs 130 of multiple dies 110 together. Referring to FIG. 11, in some embodiments, such connection is achieved by, after depositing first over-mold material layer 121 over conductive studs 130 and semiconductor dies 110, depositing an interconnect resist pattern 134 that defines a desired connection between studs 130 of different dies 110 can be deposited over seed metal layer 133. One or more interconnect contacts 145 can be deposited (e.g., by electroplating) in the desired arrangement as shown in FIG. 12. Referring next to FIG. 13, interconnect resist pattern 144 can be removed (e.g., stripped), and seed metal layer 133 can be etched, such as to remove it from un-plated portions of first over-mold material layer 121. In this arrangement, interconnect contacts 145 are operable as a redistribution layer among and between dies 110 to provide the directly-metallized electrical interconnect from die to die without solder and without the use of a pre-fabricated interposer as discussed above. For those of studs 130 that remain unconnected following the production of interconnect contacts 145, further processing can be completed to produce conductive contacts 135 to define the land grid array interface, such as by the steps outlined above with reference to FIGS. 5 through 10. As illustrated in FIG. 14, for example, these methods can thus be applied to produce a multi-die package 150 having both an array of conductive contacts 135 that define a land grid array interface and one or more interconnect contacts 145 that provide communication between multiple dies 110. In either case, the arrangement of dies 110 in the reconstituted wafer is packaged together and ready for dicing. An example of such an arrangement of dies 110 is illustrated in FIG. 15. Individual integrated circuit devices can then be singulated from the reconstituted wafer into individual package form (See, e.g., integrated circuit device 100 shown in FIG. 1 or 2A), or multi-die packages can be defined (See, e.g., examples of multi-die package 150 shown in FIGS. 2B and 2C). In any configuration, as discussed above, the final structure provides an integrated circuit device having an electrical interconnect from die 110 to conductive contact 135 without any form of pre-fabricated substrate interposer.

The present subject matter can be embodied in other forms without departure from the spirit and essential characteristics thereof. The embodiments described therefore are to be considered in all respects as illustrative and not restrictive. Although the present subject matter has been described in terms of certain preferred embodiments, other embodiments that are apparent to those of ordinary skill in the art are also within the scope of the present subject matter.

What is claimed is:

1. A method of manufacturing an integrated circuit device, the method comprising:
for each of a plurality of semiconductor dies, depositing one or more conductive stud in a directly metallized connection with a respective one of the plurality of semiconductor dies;
depositing a first over-mold material layer over the one or more conductive stud and the plurality of semiconductor dies; and
depositing one or more conductive contact in communication with the one or more conductive stud, wherein the one or more conductive contact defines a land grid array interface.

2. The method of claim 1, wherein depositing one or more conductive stud comprises depositing the one or more conductive stud in a pattern corresponding to one or more electrical contact on an active surface of each of the plurality of semiconductor dies.

3. The method of claim 1, comprising depositing a second over-mold material layer about the one or more conductive contact such that the one or more conductive contact defines the land grid array interface on a surface of the second over-mold material layer.

4. The method of claim 3, wherein one or both of the first over-mold material layer or the second over-mold material layer comprises an epoxy molding compound.

5. The method of claim 1, wherein one or both of the one or more conductive stud or the one or more conductive contact comprises copper.

6. The method of claim 1, wherein depositing one or more conductive contact comprises:
removing a portion of the first over-mold material layer that covers the one or more conductive stud;
depositing a seed metal layer over the one or more conductive stud;
depositing a resist pattern that defines a desired arrangement of the land grid array interface;
depositing the one or more conductive contact in the desired arrangement; and
removing the resist pattern.

7. The method of claim 1, wherein the plurality of semiconductor dies is arranged in a reconstituted wafer array or panel form prior to depositing the first over-mold material layer.

8. The method of claim 1, comprising singulating the plurality of semiconductor dies into individual packages.

9. The method of claim 1, comprising separating the plurality of semiconductor dies into multi-die packages.

10. The method of claim 9, wherein depositing one or more conductive contact in communication with the one or more conductive stud comprises creating an electrical interconnect between two or more of the plurality of semiconductor dies in the multi-die packages.

11. A method of manufacturing an integrated circuit device, the method comprising:
arranging a plurality of semiconductor dies in a desired configuration;
depositing one or more conductive stud in a directly metallized connection with a respective one of the plurality of semiconductor dies;
depositing a first over-mold material layer over the one or more conductive stud and the plurality of semiconductor dies; and
depositing one or more conductive contact in communication with the one or more conductive stud, wherein the one or more conductive contact defines a land grid array interface.

12. The method of claim 11, wherein arranging the plurality of semiconductor dies in a desired configuration comprises mounting the plurality of dies on an adhesive carrier.

13. The method of claim 12, comprising removing the adhesive carrier after depositing the first over-mold material layer over the one or more conductive stud and the plurality of semiconductor dies.

14. An integrated circuit device comprising:
one or more semiconductor die each comprising an active surface including one or more electrical contact;
one or more conductive stud in a directly metallized connection with the one or more electrical contact;
an over-mold structure substantially surrounding the active surface of the one or more semiconductor die and the one or more conductive stud, the over-mold structure defining an outer surface; and
one or more conductive contact formed in the outer surface of the over-mold structure, wherein each of the one or more conductive contact is connected to one of the one or more conductive stud, and wherein the one or more conductive contact defines a land grid array interface on the outer surface of the over-mold structure.

15. The device of claim 14, wherein the over-mold structure comprises an epoxy molding compound.

16. The device of claim 14, wherein one or both of the one or more conductive stud or the one or more conductive contact comprises copper.
